(19) United States
(12) Patent Application Publication
(10) Pub. No.: US 2024/0395584 A1
(43) Pub. Date: Nov. 28, 2024

(54) HEAT TREATMENT APPARATUS AND SEMICONDUCTOR SUBSTRATE MANUFACTURING METHOD

(71) Applicant: GLOBALWAFERS JAPAN CO., LTD., Kitakanbara-gun (JP)

(72) Inventors: Takuya KAKUDA, Kitakanbara-gun (JP); Manabu KATO, Kitakanbara-gun (JP); Tetsuro TAMURA, Kitakanbara-gun (JP); Haruo SUDO, Kitakanbara-gun (JP)

(73) Assignee: GLOBALWAFERS JAPAN CO., LTD., Kitakanbara-gun (JP)

(21) Appl. No.: 18/663,429

(22) Filed: May 14, 2024

(30) Foreign Application Priority Data
May 25, 2023 (JP) 2023-086286

(51) Int. Cl. H01L 21/67; G05B 19/4099; H01L 21/324; H01L 21/66

(52) U.S. Cl. CPC H01L 21/67248; G05B 19/4099; H01L 21/324; H01L 21/67115; H01L 22/26; G05B 2219/45031

(57) ABSTRACT

By accurately detecting cooling medium leakage in a heat treatment apparatus, reductions in yield and production efficiency are suppressed. A controller controls a lamp voltage or lamp current applied to a plurality of lamps based on the temperature of a semiconductor substrate detected by a temperature detector. When n is a positive integer of 2 or more, indicating the lot order of the semiconductor substrate to be treated, the controller calculates a difference effect size (n), based on the maximum lamp voltage or maximum lamp current applied to the plurality of lamps, according to equation below:

Difference effect size(n)=(maximum lamp voltage or maximum lamp current(n)−maximum lamp voltage or maximum lamp current(n−1))/standard deviation of the maximum lamp voltage or maximum lamp current in a predetermined lot range, and determines that an abnormality has occurred when the difference effect size(n)exceeds a first threshold.

### TECHNICAL FIELD

The present invention relates to a heat treatment apparatus and a method of manufacturing a semiconductor substrate, and more particularly to a heat treatment apparatus for heat treating a semiconductor substrate with the thermal energy of a lamp and a method of manufacturing a semiconductor substrate using the heat treatment apparatus.

### BACKGROUND ART

For example, a silicon wafer used as a substrate for semiconductor devices is required to have a defect-free layer in which a void defect called a crystal-originated particle (COP) does not exist on the surface, and the surface layer that will be the active regions of the semiconductor device. Rapid thermal processing (RTP) is known as a technique that responds to such a requirement.

A heat treatment apparatus performing RTP, hereinafter referred to as an RTP apparatus, can control the temperature in the wafer plane without variation when the wafer is heated to a predetermined temperature. To rapidly raise the temperature of the silicon wafer to a temperature exceeding 1200° C., the configuration of the apparatus is designed such that the radiated light of a lamp as a heat source is efficiently absorbed by the silicon wafer, and the energy loss is minimized.

Furthermore, in the RTP apparatus, cooling water, or refrigerant, for cooling the apparatus temperature circulates through the RTP apparatus to rapidly lower the temperature after rapidly raising the temperature to the maximum attainable temperature exceeding 1200° C.

For example, patent literature 1 discloses an RTP apparatus in which a lamp as a heat source is accommodated in a vertically oriented cylindrical lamp hole, and cooling water is arranged to flow adjacent to the lamp hole. Thus, the RTP apparatus can be cooled by the cooling water immediately after the heating by the lamp is completed.

### CITATION LIST

### Patent Literature

PTL 1: JP-A-2012-156522

### SUMMARY OF INVENTION

### Technical Problem

As described above, in the RTP apparatus, the cooling water (cooling medium) is circulated through the apparatus to rapidly cool the apparatus after the heating is completed.

However, there is a possibility that if the heat treatment is performed continuously with the RTP apparatus, the thermal load generated may accumulate in the circulation channel and cause damage or generate cracking in a cooling water circulation channel, resulting in cooling water leakage into the apparatus.

If the cooling water leaks into the apparatus, the moisture that has leaked into the chamber during the heat treatment process becomes water vapor, causing scattering of the radiation of thermal energy radiation. This prevents obtaining silicon wafers with the desired performance and reduces the yield, which is problematic.

The present invention has been made under such circumstances, and an object of the present invention is to provide a heat treatment apparatus capable of suppressing reductions in yield and production efficiency by accurately detecting the leakage of cooling medium in the heat treatment apparatus, and a semiconductor substrate manufacturing method using the heat treatment apparatus.

A heat treatment apparatus according to the present invention, which is made to solve the above problems, is a heat treatment apparatus that continuously performs heat treatment on a plurality of semiconductor substrates on a lot basis, and the heat treatment apparatus includes a plurality of lamps that heat the semiconductor substrate, a power source that applies a lamp voltage to the plurality of lamps, a temperature detector that detects the temperature of the semiconductor substrate, and a controller that controls a lamp voltage or a lamp current applied to the plurality of lamps and detects an abnormality in the heat treatment apparatus. The controller controls the lamp voltage or the lamp current applied to the plurality of lamps based on the temperature of the semiconductor substrate detected by the temperature detector. When n denotes a positive integer of 2 or more indicating the order of the lot of the semiconductor substrate to be treated, the controller calculates a difference effect size (n) based on a maximum lamp voltage or a maximum lamp current applied to the plurality of lamps, by using an equation below:

difference effect size(n)=(maximum lamp voltage or maximum lamp current(n)−maximum lamp voltage or maximum lamp current(n−1))/standard deviation of the maximum lamp voltage or maximum lamp current in a predetermined batch range, and

the controller determines that an abnormality occurs when the difference effect size (n) exceeds a first threshold.

Preferably, the heat treatment apparatus further includes a warning unit that issues a warning of an abnormality in the heat treatment apparatus by a display or a voice, and when the controller determines that an abnormality has occurred, the warning unit issues a warning.

In addition, the first threshold is preferably 1.2 or more and 3.0 or less.

Thus, the occurrence of cooling water leakage is detected by comparing the difference effect size obtained by dividing the difference which is obtained by subtracting the maximum lamp voltage or maximum lamp current (n−1) from the maximum lamp voltage or maximum lamp current (n) by the standard deviation o of the maximum lamp voltage or lamp current in the predetermined lot range with the first threshold.

This makes it possible to eliminate an accidental rapid increase in the lamp voltage caused by a factor other than the cooling water leakage and to accurately detect the cooling water leakage.

As a result, yield and productivity loss can be suppressed by taking immediate action such as stopping and repairing the heat treatment apparatus.

Further, a heat treatment apparatus according to the present invention, which is made to solve the above problems, is a heat treatment apparatus that continuously performs heat treatment on a plurality of semiconductor substrates on a lot basis, and the heat treatment apparatus includes a plurality of lamps that heat the semiconductor substrate, a power source that applies a lamp voltage to the plurality of lamps, a temperature detector that detects the temperature of the semiconductor substrate, and a controller that controls a lamp voltage applied to the plurality of lamps and detects an abnormality in the heat treatment apparatus. The controller controls the lamp voltage or the lamp current applied to the plurality of lamps based on the temperature of the semiconductor substrate detected by the temperature detector. When n denotes a positive integer of 2 or more, indicating the order of the lot of the semiconductor substrates to be treated, the controller calculates a difference effect size (n), based on a maximum lamp voltage or a maximum lamp current applied to the plurality of lamps, by using an equation below:

difference effect size(n)=(maximum lamp voltage or maximum lamp current(n)−maximum lamp voltage or maximum lamp current(n−1))/standard deviation of the maximum lamp voltage or maximum lamp current in a predetermined lot range.

The controller further calculates a second-order difference effect size (n) by using the following equation:

second-order difference effect size(n)=difference effect size(n)−difference effect size(n−1), or

(difference(n)of the maximum lamp voltage or the maximum lamp current−difference(−1) of the maximum lamp voltage or the maximum lamp current)/standard deviation of the difference(n)of the maximum lamp voltage or the maximum lamp current in a predetermined lot range. Further, the controller determines that an abnormality has occurred when the difference effect size(n)exceeds a first threshold, and the second-order difference effect size falls within a range above a second threshold and below a third threshold.

Preferably, the heat treatment apparatus further includes a warning unit that issues a warning about an abnormality in the heat treatment apparatus through a display or a voice, and when the controller determines that an abnormality has occurred, the warning unit issues a warning.

Preferably, the first threshold is 1.2 or more and 3.0 or less, the second threshold is −1.5 or more and −0.7 or less, and the third threshold is 0.7 or more and 1.5 or less.

As described above, cooling water leakage has been detected using the difference effect size d(n) which is obtained by dividing the difference, obtained by subtracting the maximum lamp voltage V(n−1) at lot (n) from the maximum lamp voltage V(n) at lot (n), by the standard deviation σ of the maximum lamp voltage in the predetermined lot range; and the second-order difference effect size D(n) that is the difference between the difference effect size d(n) and the difference effect size d(n−1).

That is, by using not only the difference effect size d(n) but also the second-order difference effect size D(n), it is possible to distinguish between an accidental variation of the maximum lamp voltage V(n) and a systematic variation due to leakage and to detect cooling water leakage more accurately.

As a result, yield and productivity losses can be suppressed by taking immediate action such as stopping and repairing the heat treatment apparatus.

Further, a semiconductor substrate manufacturing method according to the present invention, which is made to solve the above problems, is a semiconductor substrate manufacturing method for manufacturing a semiconductor substrate by using the heat treatment apparatus which continuously performs heat treatment on a plurality of semiconductor substrates on a lot basis.

The semiconductor substrate manufacturing method includes a step of controlling a lamp voltage or a lamp current applied to a plurality of lamps by the controller and heating a semiconductor substrate using the plurality of lamps,
a step of detecting the temperature of the semiconductor substrate by the controller using the temperature detector and controlling the lamp voltage or the lamp current applied to the plurality of lamps based on the temperature of the semiconductor substrate, and
a step of calculating a difference effect size (n), based on a maximum lamp voltage or a maximum lamp current applied to the plurality of lamps, using an equation below:

difference effect size(n)=(maximum lamp voltage or maximum lamp current(n)−maximum lamp voltage or maximum lamp current(n−1))/standard deviation of the maximum lamp voltage or maximum lamp current in predetermined lot range, where n is a positive integer of 2 or more, indicating a lot order,

wherein the controller determines that an abnormality has occurred when the difference effect size (n) exceeds the first threshold. Preferably, when the controller determines that an abnormality has occurred, a warning unit that issues a warning about an abnormality in the heat treatment apparatus through a display or a voice warns of the abnormality.

In addition, the first threshold is preferably 1.2 or more and 3.0 or less.

According to such a method, the occurrence of cooling water leakage is detected by comparing the difference effect size obtained by dividing the difference, obtained by subtracting the maximum lamp voltage or current (n−1) from the maximum lamp voltage or current (n), by the standard deviation o of the maximum lamp voltage or maximum lamp current in the predetermined lot range with the first threshold.

This makes it possible to eliminate an accidental rapid increase in the maximum lamp voltage caused by a factor other than the cooling water leakage and to accurately detect the cooling water leakage.

As a result, the loss of yield and productivity can be suppressed by taking immediate action such as stopping and repairing the heat treatment apparatus.

Further, a semiconductor substrate manufacturing method according to the present invention, which is made to solve the above problems, is a semiconductor substrate manufacturing method for manufacturing a semiconductor substrate by using the heat treatment apparatus which performs continuous heat treatment operations on a plurality of semiconductor substrates on a lot-by-lot basis. The semiconductor substrate manufacturing method includes
a step of controlling a lamp voltage or a lamp current applied to a plurality of lamps by the controller and heating a semiconductor substrate by using the plurality of lamps,
a step of detecting the temperature of the semiconductor substrate by using the temperature detector and controlling the lamp voltage applied to the plurality of lamps by the controller based on the temperature of the semiconductor substrate, and
a step of calculating a difference effect size (n) based on a maximum lamp voltage or a maximum lamp current applied to the plurality of lamps, where n is a positive integer of 2 or more, indicating a lot order of the semiconductor substrate to be treated, using the following equation: difference effect size (n)=(maximum lamp voltage or maximum lamp current (n)−maximum lamp voltage or maximum lamp current (n−1))/standard deviation of maximum lamp voltage or maximum lamp current in the predetermined lot range, and further calculating a second-order difference effect size (n) using the following equation: second-order difference effect size (n)=difference effect size (n)−difference effect size (n−1), or (difference (n) of the maximum lamp voltage or the maximum lamp current−difference (n−1) of the maximum lamp voltage or the maximum lamp current)/standard deviation of the difference (n) of the maximum lamp voltage or the maximum lamp current in the predetermined lot range, wherein the controller determines that an abnormality has occurred when the difference effect size (n) exceeds the first threshold and the second-order difference effect size falls within a range above a second threshold and below a third threshold.

Preferably, when the controller determines that an abnormality has occurred, a warning unit that issues a warning about an abnormality in the heat treatment apparatus through a display or a voice warns of the abnormality.

Preferably, the first threshold is 1.2 or more and 3.0 or less, the second threshold is −1.5 or more and −0.7 or less, and the third threshold is 0.7 or more and 1.5 or less.

According to such a method, the occurrence of cooling water leakage has been detected using: the difference effect size d(n−1) obtained by dividing the difference, obtained by subtracting the maximum lamp voltage V(n−1) in the lot (n) from the maximum lamp voltage V(n) in the lot (n), by the standard deviation o of the lamp voltage; and the second-order difference effect size D(n) that is the difference between the difference effect size d(n) and the difference effect size d(n−1).

That is, by using not only the difference effect size d(n) but also the second-order difference effect size D(n), it is possible to distinguish between an accidental variation of the maximum lamp voltage V(n) and a systematic variation due to leakage and to detect cooling water leakage more accurately.

As a result, the loss of yield and productivity can be suppressed by taking immediate action such as stopping and repairing the heat treatment apparatus.

### Advantageous Effect of Invention

According to the present invention, the loss of yield and production efficiency can be suppressed by accurately detecting cooling medium leakage in a heat treatment apparatus.

### BRIEF DESCRIPTION OF DRAWINGS

FIG. 1 is a cross-sectional view schematically illustrating an RTP apparatus (heat treatment apparatus) according to an embodiment of the present invention;

FIG. 2 is an enlarged cross-sectional view of a halogen lamp provided in the RTP apparatus of FIG. 1;

FIG. 3 is a flowchart illustrating a first embodiment of a semiconductor substrate manufacturing method according to the present invention;

FIG. 4 is a flowchart illustrating a second embodiment of a semiconductor substrate manufacturing method according to the present invention;

FIG. 5 is a graph illustrating the results of Experiment 1 of the example;

FIGS. 6A and 6B are other graphs illustrating the results of Experiment 1 of the example; and

FIG. 7 is another graph illustrating the results of Experiment 1 of the example.

### DESCRIPTION OF EMBODIMENTS

Embodiments of the present invention will be described in detail below with reference to the drawings and the like.

The embodiments of the present invention will be described using examples of an RTP apparatus or a heat treatment apparatus in which a lamp such as a high-voltage tungsten halogen lamp disposed in a lamp sleeve is a heat source.

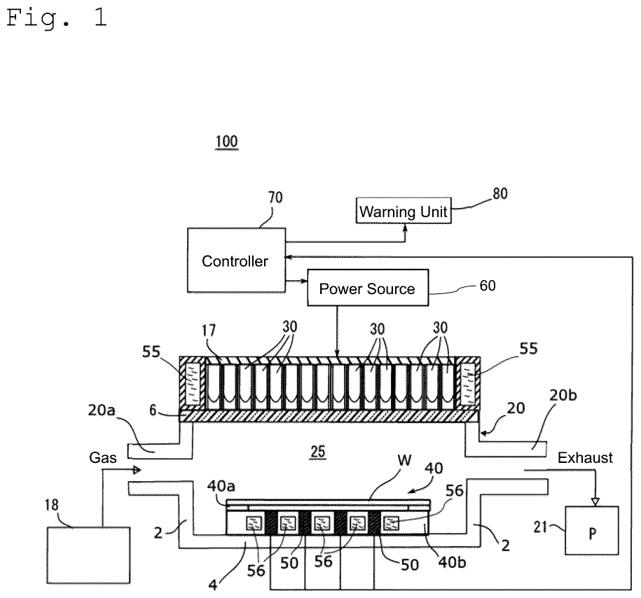

FIG. 1 is a cross-sectional view schematically illustrating an RTP apparatus 100, or a heat treatment apparatus, according to an embodiment of the present invention. The RTP apparatus 100 includes a chamber 20, and the chamber 20 includes a chamber sidewall 2, a chamber bottom 4 coupled to the chamber sidewall 2, and a quartz window 6 disposed above the chamber sidewall 2.

The chamber sidewall 2, the chamber bottom 4, and the quartz window 6 forming the chamber 20 form a reaction space 25 for processing a silicon wafer W, or a semiconductor substrate, therein. The RTP apparatus 100 is provided with a slit valve door, not shown, which penetrates the chamber sidewall 2 to transfer the silicon wafer W into the reaction space 25.

The RTP apparatus 100 includes a gas introduction port 20a formed in the chamber sidewall 2, and the gas introduction port 20a is connected to a gas supply source 18 configured to provide one or more processing gases to the reaction space 25. The RTP apparatus 100 includes a gas exhaust port 20b formed in the chamber sidewall 2, and the gas exhaust port 20b is connected to a vacuum pump 21 for exhausting gas from the reaction space 25 to the outside.

Further, the RTP apparatus 100 includes a substrate support 40 for supporting the silicon wafer W in the reaction space 25 in the chamber 20. Further, although not shown, a rotation means is provided for rotating the silicon wafer W about its central axis at a predetermined speed.

The substrate support 40 is provided with an annular susceptor 40a that supports the outer peripheral portion of the silicon wafer W, and a stage 40b that supports the susceptor 40a.

The temperature of the silicon wafer W in the RTP apparatus 100 is controlled using a plurality of radiation thermometers 50, or temperature detectors, embedded in the stage 40b of the substrate support 40. The radiation thermometers 50 are connected to a controller 70 which is a computer, and the controller 70 controls the temperature of the silicon wafer W based on the temperature information of the silicon wafer W acquired by the radiation thermometer 50.

That is, the controller 70 measures the temperatures of a plurality of points, such as nine points, in the substrate plane in the substrate radial direction at the bottom of the silicon wafer W with the radiation thermometer 50. Based on the measured temperatures, the controller 70 performs control of a plurality of halogen lamps 30, such as individual ON-OFF control of each lamp, increase/decrease control of supplied power, and control of the light emission intensity of light to be emitted.

The plurality of halogen lamps 30 are disposed above the quartz window 6 and are configured to transmit thermal energy through the quartz window 6 toward the silicon wafer W. The plurality of halogen lamps 30 are arranged in such as a hexagonal pattern in plan view. Each of the plurality of halogen lamps 30 is connected to the heating assembly base 17 for electrical connection to the power source 60.

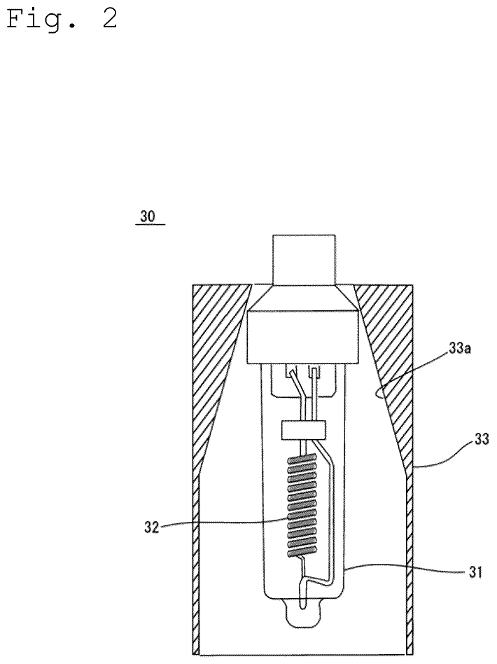

Each halogen lamp 30 is configured, for example, as shown in FIG. 2. In the halogen lamp 30 shown in FIG. 2, a tungsten filament coil 32 is disposed within a lamp glass 31 formed of quartz glass, and a gas containing a halogen gas is sealed within the lamp glass 31.

The lamp glass 31 is surrounded by a tubular lamp sleeve 33, and an inner wall 33a of the lamp sleeve 33 is inclined so that thermal energy emitted from the lamp glass 31 is directed to the lower silicon wafer W. The inner wall 33a of the lamp sleeve 33 is preferably plated with gold (Au). This is because the gold (Au) plating has high heat resistance, high reflectivity, and high acid resistance.

A lamp voltage is applied to each halogen lamp 30 from the power source 60. The value of the lamp voltage is controlled by the controller 70.

In the present embodiment, as shown in FIG. 1, a cooling water path 55 is configured to circulate cooling water, or a cooling medium, for rapidly cooling the heat of the halogen lamps 30 after the heat treatment is provided around the plurality of halogen lamps 30. Further, a cooling water path 56 is provided in the stage 40b of the substrate support 40, and the stage 40b and the silicon wafer W thereon can be rapidly cooled after the heat treatment.

Further, the RTP apparatus 100 according to the present embodiment is provided with a warning unit 80 for warning of the occurrence of cooling water leakage from the cooling water paths 55, 56 for example, by a screen display or a warning sound or voice.

Specifically, the controller 70 issues a warning through the warning unit 80 when the amount of the effect calculated according to the following Eq. 1, which will be referred to as a difference effect size, exceeds the first threshold set at 1.2, for example, during the continuous operation of the silicon wafer W processed in lot units such as 25 wafers.

Note that the heat treatment apparatus according to the present invention is not limited to issuing the warning as in the present embodiment, and the heat treatment apparatus may be automatically stopped without warning.

The first threshold is determined by setting a voltage threshold for classification as “not acceptable” due to a rapid increase in the maximum lamp voltage in each of a plurality of heat treatment recipes and specifying a range of a difference effect size in which there are a large number of lots that are classified as “not acceptable”, that is, lots with the maximum lamp voltage exceeding the voltage threshold, in each recipe.

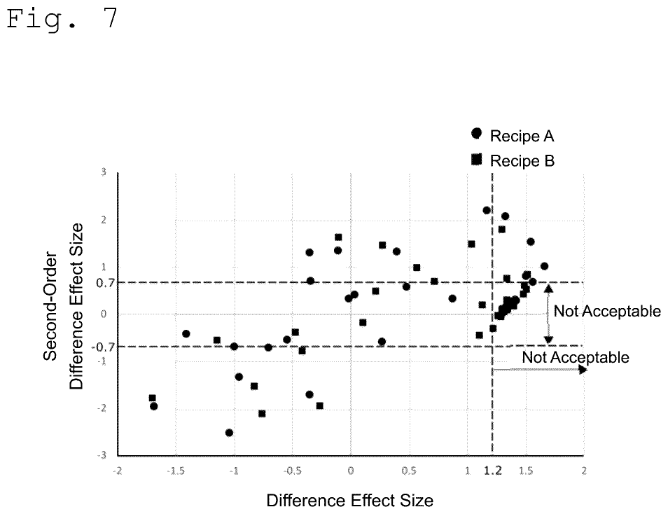

Specifically, for example, in the example shown in FIG. 7, the first threshold may be set to 1.2 because the number of “not acceptable” cases is higher when the difference effect size exceeds 1.2 and there are no “not acceptable” cases when the difference effect size is less than 1.2. Alternatively, the first threshold may be appropriately set in the range of 1.2 or more and 3.0 or less, because there are some lots not classified as “not acceptable” in the range where the difference effect size is 1.2 or more and 3.0 or less. However, in the present invention, a value exceeding 3.0 is not necessarily excluded as the first threshold.

Difference effect size d(n)=(maximum lamp voltage V(n)−maximum lamp voltage V(n−1))/standard deviation σ. (1)

The difference effect size d(n) calculated by Eq. 1is obtained by dividing the difference between the maximum lamp voltage or the maximum lamp current in the nth lot, where n is a positive integer of 2 or more, and the maximum lamp voltage, or the maximum lamp current in the previous lot (n−1) by the standard deviation o of the maximum lamp voltage or the maximum lamp current in a predetermined lot range, such as the standard deviation in the last 25wafers, that is, the last 5 lots, of silicon wafers W when 5 wafers are used per lot.

Note that one (1) lot is preferably set to contain the range of 1 to 50 wafers. If the number of wafers exceeds 50 wafers per lot, early detection of cooling water leakage may be delayed, but the number of wafers exceeding 50 wafers is not necessarily precluded.

The predetermined lot range is preferably set to 2 to 30 lots of the previous lot of the same recipe, but can be set without being limited to this range.

The maximum lamp voltage or the maximum lamp current in the predetermined lot range may be the maximum value or an average value of the maximum lamp voltage in one (1) lot range.

More preferably, the second-order difference effect size D(n) is calculated according to the following Eq. 2.If the difference effect size d(n) exceeds the first threshold, e.g., 1.2, and the second-order difference effect size D(n) falls within a range above a second threshold and below a third threshold, e.g., more than −0.7 and less than 0.7, an abnormality is determined and the warning unit 80 issues a warning.

Similarly to the first threshold, the second threshold and the third threshold are determined by setting a voltage threshold for “not acceptable” due to a rapid increase in the maximum lamp voltage in each of a plurality of heat treatment recipes and specifying a region of a second-order difference effect size in which there are a large number of lots that are specified as “not acceptable” (e.g., lots with the maximum lamp voltage exceeding the voltage threshold) in each recipe.

Specifically, in the example shown in FIG. 7, the second threshold may be set to −0.7 and the third threshold may be set to 0.7 because the number of “not acceptable” cases is higher in a region where the second-order difference effect size is greater than −0.7 and less than 0.7, and the number of “not acceptable” cases is lower in other regions.

Alternatively, the second threshold may be set in the range of −1.5 or more and −0.7 or less, and the third threshold may be set in the range of 0.7 or more and 1.5 or less. This is because there are lots not classified as “not acceptable” even in the range where the second-order difference effect size is −1.5 or more and −0.7 or less, and there are lots not classified as “not acceptable” even in the range where the second-order difference effect size is 0.7 or more and 1.5 or less.

Second-order difference effect size D(n)=Difference effect size d(n)−Difference effect size d(n−1). (2)

The second-order difference effect size D(n) calculated by Eq. 2 is the difference between the difference effect size in the nth lot (n) and the difference effect size in the previous lot (n−1).

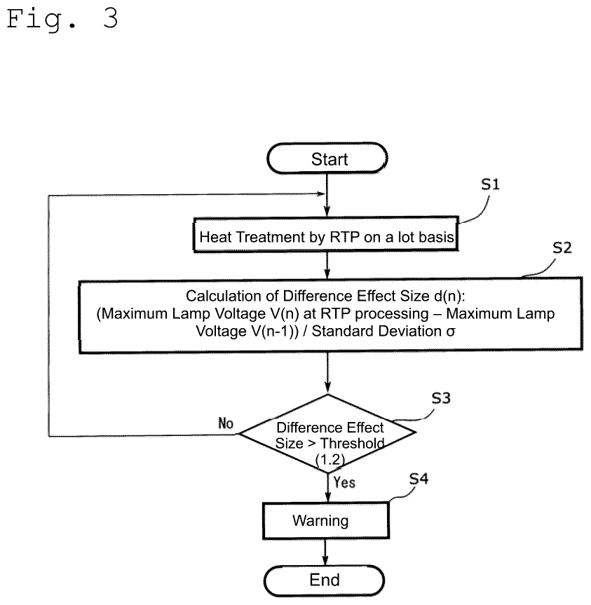

Next, a first embodiment of a semiconductor substrate manufacturing method using the heat treatment apparatus according to the present invention will be described based on the flowchart of FIG. 3.

In the RTP apparatus 100 shown in FIG. 1, heat treatment is continuously performed on a plurality of lots, each lot containing, for example, 25 wafers. The heat treatment for the nth lot, where n is a positive integer of 2 or more, of silicon wafers W is performed as follows in step S1 of FIG. 3.

That is, in the heat treatment for each silicon wafer W, the silicon wafer W is first accommodated in the chamber 20 and maintained at a desired initial temperature.

After the silicon wafer is placed, a gas obtained by mixing oxygen (O₂) and an inert gas is introduced into the chamber 20 from the gas introduction port 20a at a predetermined flow rate. Examples of the inert gases include Ar gas and nitrogen gas.

Then, for example, in a case where the silicon wafer W is heat-treated at a target temperature of 1300° C., the controller 70 determines a lamp voltage, which is an initial setting voltage, applied to the corresponding halogen lamp 30, and applies the lamp voltage to each halogen lamp 30 using the power source 60. Each halogen lamp 30 radiates thermal energy corresponding to the applied lamp voltage toward the silicon wafer W, thereby starting to heat the silicon wafer.

During the heating of the silicon wafer W, the temperatures of a plurality of points, for example, nine points, in the substrate plane in the substrate radial direction at the bottom of the silicon wafer W are measured by the radiation thermometer 50. The controller 70 controls the voltage applied to the halogen lamp 30 based on the measured temperature of the silicon wafer W.

When cooling water leakage occurs in the RTP apparatus 100 the radiation of thermal energy is blocked by the generation of water vapor, for example, so that the temperature of the silicon wafer W decreases, and the controller 70 performs control to increase the applied voltage to the halogen lamp 30.

Then, when the substrate temperature reaches a target temperature of, for example, 1300° C., due to the voltage applied to the halogen lamps 30, and a predetermined time has elapsed at that temperature, the heat treatment of the silicon wafer W is terminated.

Next, after the entire heat treatment for the nth lot, where n is a positive integer of 2 or more, of silicon wafers W, exemplified by 25 wafers, is completed, the difference effect size d(n) is calculated based on the following Eq. 1 (step S2 of FIG. 3.)

$$Difference effect size d ( n ) = ( maximum lamp voltage V ( n ) - maximum lamp voltage V ( n - 1 ) ) / standard deviation σ of maximum lamp voltage V in the predetermined lot range . \qquad ( 1 )$$

When the difference effect size d(n) is obtained, the controller 70 determines whether or not the difference effect size d(n) exceeds the first threshold, e.g., 1.2 (step S3 of FIG. 3.)

Here, when the difference effect size d(n) does not exceed the first threshold, the process returns to the step S1 to perform the heat treatment on the next lot (n+1).

On the other hand, when the difference effect size d(n) exceeds the first threshold, the controller 70 determines that an abnormality, which is a leakage of the cooling water, has occurred, and the warning unit 80 issues a warning indicating that a leakage of the cooling water has occurred through a display on the screen or the like or a voice (step S4 of FIG. 3.)

When the warning is issued by the warning unit 80, after stopping the operation of the RTP apparatus 100, an operator may check and repair the site of the abnormality and resume the operation of the RTP apparatus 100.

When it is determined in the step S3 that an abnormality has occurred in the RTP apparatus 100, the controller 70 may control the operation of the RTP apparatus 100 to be automatically stopped.

As described above, according to the first embodiment of the semiconductor substrate manufacturing method of the present invention, the occurrence of cooling water leakage is detected by comparing the difference effect size obtained by dividing the difference, obtained by subtracting the maximum lamp voltage V(n−1) from the maximum lamp voltage V(n) by the standard deviation o of the lamp voltage or current with the first threshold.

This makes it possible to eliminate an accidental rapid increase in the lamp voltage caused by a factor other than cooling water leakage to accurately detect cooling water leakage.

As a result, it is possible to suppress the decrease in yield and production efficiency by taking immediate action such as repair.

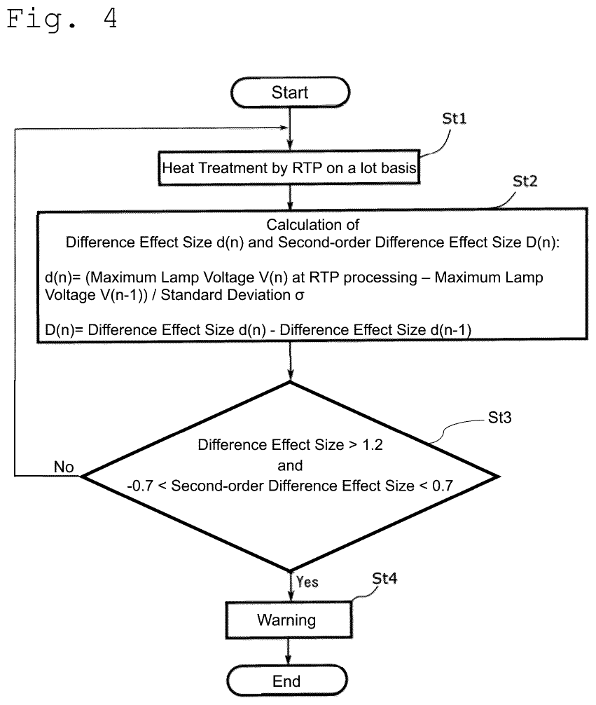

Next, a second embodiment of the semiconductor substrate manufacturing method, using the heat treatment apparatus according to the present invention, will be described based on the flowchart of FIG. 4.

In the RTP apparatus 100 shown in FIG. 1, heat treatment is continuously performed on a plurality of lots, with each lot containing, for example, 25 wafers. The heat treatment for the nth lot, where n is a positive integer of 2 or more, of silicon wafers W is performed as follows in step St1 of FIG. 4.

That is, in the heat treatment for each silicon wafer W, the silicon wafer W is first housed in the chamber 20 and kept at a desired initial temperature.

After the placement of the silicon wafer, a gas obtained by mixing oxygen (O₂) and an inert gas is introduced into the chamber 20 from the gas introduction port 20a at a predetermined flow rate. Examples of the inert gases include argon (Ar) gas and nitrogen (N₂) gas.

Then, for example, in a case where the silicon wafer W is heat-treated at a target temperature of 1300° C., the controller 70 determines a lamp voltage, which is an initial setting voltage, to be applied to the corresponding halogen lamp 30, and applies the lamp voltage to each halogen lamp 30 using the power source 60. Each halogen lamp 30 radiates thermal energy corresponding to the applied lamp voltage toward the silicon wafer W, thereby starting to heat the silicon wafer W.

During the heating of the silicon wafer W, the temperatures of a plurality of points, for example, nine points, in the substrate plane in the substrate radial direction at the bottom of the silicon wafer W are measured by the radiation thermometer 50. The controller 70 controls the applied voltage to the halogen lamp 30 based on the measured temperature of the silicon wafer W.

For example, when cooling water leakage occurs in the RTP apparatus 100 the radiation of thermal energy is blocked by the generation of water vapor, so that the temperature of the silicon wafer W decreases, and the controller 70 performs control to increase the applied voltage to the halogen lamp 30.

Then, when the substrate temperature reaches a target temperature of, for example, 1300° C., due to the voltage applied to the halogen lamps 30, and a predetermined time has elapsed at that temperature, the heat treatment of the silicon wafer W is terminated.

Next, after the entire heat treatment for the nth lot, where n is a positive integer of 2 or more, of silicon wafers W, exemplified by 25 wafers, is completed, the difference effect size d(n) and the second-order difference effect size D(n) are calculated based on the following Eqs. 1 and 2 (Step St 2 of FIG. 4.)

$$Difference effect size d ( n ) = ( maximum lamp voltage V ( n ) - maximum lamp voltage V ( n - 1 ) ) / standard deviation σ of the maximum lamp voltage V in a predetermined lot range . \qquad ( 1 )$$

$$Second - order difference effect size D ( n ) = Difference effect size d ( n ) - Difference effect size d ( n - 1 ) . \qquad ( 2 )$$

Note that the second-order difference effect size D(n) may be obtained by using the following Eq. 3:

$$Second - order difference effect size D ( n ) = ( difference v ( n ) of the maximum lamp voltage - difference v ( n - 1 ) of the maximum lamp voltage ) / standard deviation σ of the difference ( n ) of the maximum lamp voltage V in the predetermined lot range . \qquad ( 3 )$$

In Eq. 3, the difference v(n) of the maximum lamp voltage is the difference between the maximum lamp voltage V in the lot (n) and the previously processed lot (n−1).

When the difference effect size d(n) and the second-order difference effect size D(n) are obtained, the controller 70 determines whether the difference effect size d(n) exceeds the first threshold, e.g., 1.2, and whether the second-order difference effect size D(n) falls within the range above the second threshold and below the third threshold, e.g., more than −0.7 and less than 0.7 (Step St3 of FIG. 4.)

Here, if the difference effect size d(n) does not exceed the first threshold, or if the second-order difference effect size D(n) does not fall within the range above the second threshold and below the third threshold, e.g., more than −0.7 and less than 0.7, even if the difference effect size d(n) exceeds the first threshold, the method returns to step St1 to perform the heat treatment on the next lot (n+1).

On the other hand, when the difference effect size d(n) exceeds the first threshold, e.g., 1.2, and the second-order difference effect size D(n) falls within the range above the second threshold and below the third threshold, e.g., more than −0.7 and less than 0.7, the controller 70 determines that an abnormality (cooling water leakage) has occurred, and the warning unit 80 issues a warning indicating that cooling water leakage has occurred through a display on the screen or the like or a voice. (Step St4 of FIG. 4)

When the warning is issued by the warning unit 80, after stopping the operation of the RTP apparatus 100, the operator may check and repair the location of the abnormality and resume the operation of the RTP apparatus 100.

When it is determined in step St3 that an abnormality has occurred in the RTP apparatus 100, the controller 70 may control the operation of the RTP apparatus 100 to be automatically stopped.

As described above, according to the second embodiment of the semiconductor substrate manufacturing method of the present invention, the occurrence of cooling water leakage is detected using: the difference effect size d(n−1), which is obtained by dividing the difference, obtained by subtracting the maximum lamp voltage V(n−1) in the lot (n) from the maximum lamp voltage V(n) in the lot (n), by the standard deviation o of the lamp voltage; and the second-order difference effect size D(n), which is the difference between the difference effect size d(n) and the difference effect size d(n−1).

That is, by using not only the difference effect size d(n) but also the second-order difference effect size D(n), it is possible to distinguish between an accidental variation of the maximum lamp voltage V(n) and a systematic variation due to leakage and to detect cooling water leakage more accurately.

As a result, it is possible to inhibit loss of yield and production efficiency through immediate action, such as repair.

In the first and second embodiments, the difference effect size and the second-order difference effect size were obtained using the maximum lamp voltage applied to the halogen lamp 30. However, the present invention is not limited to this example, and the difference effect size and the second-order difference effect size may be obtained using the maximum lamp current applied to the halogen lamp 30.

In that case, the maximum lamp voltage in each of Eqs. 1, 2, and 3 described above is to be replaced by the maximum lamp current.

In addition, in the first and second embodiments, the silicon wafer has been described as an example of the semiconductor substrate, but the present invention is not limited thereto, and a SiC wafer, a GaN wafer, a device-formed wafer, or the like may be used as the semiconductor substrate.

### EXAMPLES

Hereinafter, the present invention will be more particularly described by reference to examples, but the present invention is not to be construed as limited by the following examples.

### Experiment 1

In Experiment 1, the RTP apparatus was operated continuously on a lot basis, and the change in the maximum lamp voltage was measured to verify the first, second, and third thresholds for the difference effect size and the second-order difference effect size.

First, continuous operation was performed on silicon wafers for semiconductor devices in the RTP apparatus for two different recipes, in a heat treatment process with a heating temperature of 1300° C. for 40 seconds for recipe A and 1350° C. for 35 seconds for recipe B. For both recipes A and B, each lot contains 25 silicon wafers, and 39 lots were continuously heat treated.

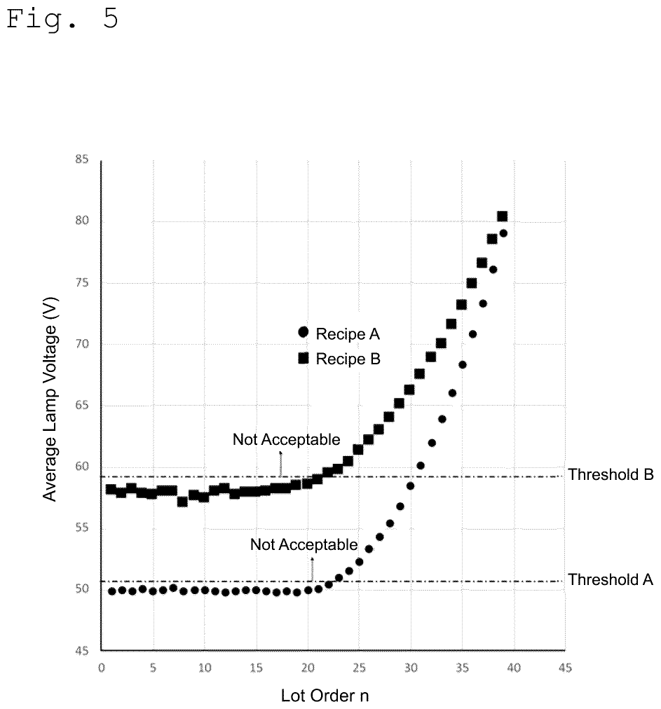

The graph of FIG. 5 shows the relationship between the maximum lamp voltage V, represented on the vertical axis, and the lot order, represented on the horizontal axis, in each lot for Recipes A and B.

For the plot data of each of the Recipes A and B, cooling water leakage occurred at lamp voltages exceeding the thresholds A and B, respectively.

Then, from the data shown in the graph of FIG. 5, the difference effect size was obtained based on the following Eq. 1, the second-order difference effect size was obtained based on the following Eq. 2, and a graph of the correlation between the difference effect size and the second-order difference effect size was drawn.

$$Difference effect size d ( n ) = ( maximum lamp voltage V ( n ) during RTP - maximum lamp voltage V ( n - 1 ) ) / standard deviation σ of the maximum lamp voltage V in the predetermined lot range . \qquad ( 1 )$$

$$Second - order difference effect size D ( n ) = Difference effect size d ( n ) - Difference effect size d ( n - 1 ) . \qquad ( 2 )$$

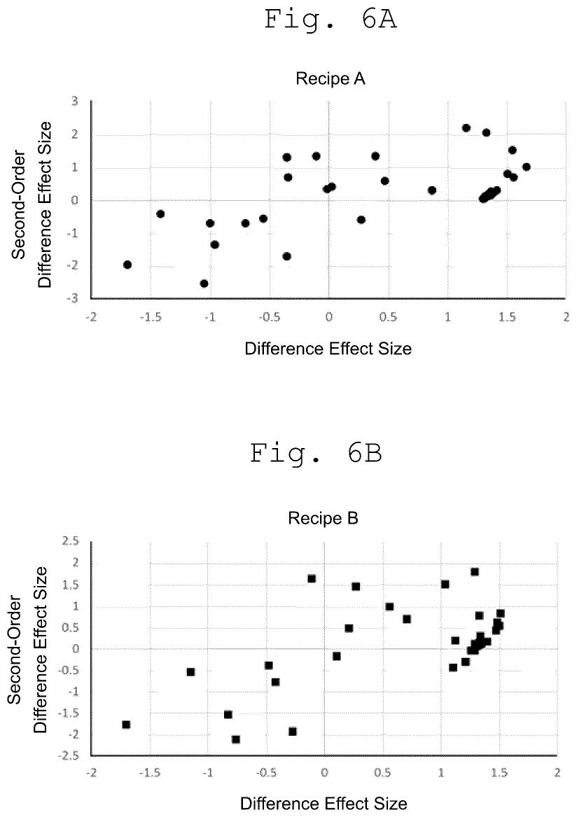

FIG. 6A illustrates a graph of the correlation between the difference effect size and the second-order difference effect size for Recipe A, and FIG. 6B illustrates a graph of the correlation between the difference effect size and the second-order difference effect size for Recipe B. In FIGS. 6A and 6B, the vertical axis represents the second-order difference effect size, and the horizontal axis represents the difference effect size.

Next, as shown in FIG. 7, FIGS. 6A and 6B are overlaid on the same graph to specify a region where there are many lots where the maximum lamp voltage is higher than the thresholds A and B as shown in FIG. 5, namely, those identified as “not acceptable”.

As a result, in many cases where the difference effect size exceeds the threshold of 1.2 in the lot, it is found that the maximum lamp voltage was the lamp voltage that caused cooling water leakage to occur.

Thus, under the conditions of Experiment 1, it is confirmed that it is preferable to issue a warning in the RTP apparatus when the difference effect size exceeds the threshold of 1.2. Alternatively, since there were some lots with differential effect sizes between 1.2 and 3.0 that were not unacceptable, it was confirmed that the first threshold should be set appropriately in the range of 1.2 to 3.0.

In addition, it is found that the maximum lamp voltage was the lamp voltage that caused cooling water leakage to occur when the difference effect size exceeded 1.2 (the first threshold) and the second-order difference effect size fell within the range of more than −0.7 (the second threshold) and less than 0.7 (the third threshold).

Thus, it was confirmed that it is further preferable to issue a warning in the RTP apparatus when the difference effect size exceeds 1.2, which is the first threshold, and the second-order difference effect size falls within the range of more than −0.7, which is the second threshold, and less than 0.7, which is the third threshold, as in the second embodiment.

It was confirmed that, alternatively, the second threshold may be set as appropriate in the range of −1.5 or more and −0.7 or less, and the third threshold may be set as appropriate in the range of 0.7 or more and 1.5 or less. This is because there were lots that were not classified as NG even in the range where the second-order difference effect size is −1.5 or more and −0.7 or less, and there were lots that were not classified as “not acceptable” even in the range where the second-order difference effect size is 0.7 or more and 1.5 or less.

### REFERENCE SIGNS LIST

20 chamber
20a gas introduction port
20b gas exhaust port
25 reaction space
30 halogen lamp (lamp)
40 substrate support
40a susceptor
50 radiation thermometer
60 power source
70 controller
80 warning unit
W silicon wafer

What is claimed is:

1. A heat treatment apparatus that continuously performs heat treatment on a plurality of semiconductor substrates on a lot basis, the heat treatment apparatus comprising:
a plurality of lamps that heats the semiconductor substrate;
a power source that supplies a lamp voltage to the plurality of lamps;
a temperature detector that detects the temperature of the semiconductor substrate; and
a controller that controls the lamp voltage or a lamp current applied to the plurality of lamps and detects an abnormality in the heat treatment apparatus,
wherein
the controller controls the lamp voltage or the lamp current applied to the plurality of lamps based on the temperature of the semiconductor substrate detected by the temperature detector,
when n is a positive integer of 2 or more indicating the order of the lot of the semiconductor substrate to be treated, the controller calculates a difference effect size (n), based on a maximum lamp voltage or a maximum lamp current applied to the plurality of lamps, according to an equation below:
Difference effect size(n)=(maximum lamp voltage or maximum lamp current(n)−maximum lamp voltage or maximum lamp current(n−1))/standard deviation of the maximum lamp voltage or maximum lamp current in the predetermined lot range,
and the controller determines that an abnormality has occurred when the difference effect size (n) exceeds a first threshold.

2. The heat treatment apparatus according to claim 1, further comprising
a warning unit that issues a warning about an abnormality in the heat treatment apparatus through a display or a voice,
wherein when the controller determines that an abnormality has occurred, the warning unit issues a warning.

3. The heat treatment apparatus according to claim 1, wherein the first threshold is 1.2 or more and 3.0 or less.

4. A heat treatment apparatus that continuously performs heat treatment on a plurality of semiconductor substrates on a lot basis, the heat treatment apparatus, comprising:
a plurality of lamps that heats the semiconductor substrate;
a power source that applies a lamp voltage to the plurality of lamps;
a temperature detector that detects the temperature of the semiconductor substrate; and
a controller that controls the lamp voltage applied to the plurality of lamps and detects the abnormality in the heat treatment apparatus,
wherein
the controller controls the lamp voltage or the lamp current applied to the plurality of lamps based on the temperature of the semiconductor substrate detected by the temperature detector, and
when n is a positive integer of 2 or more, indicating the order of the lot of the semiconductor substrate to be treated, the controller calculates a difference effect size (n), based on a maximum lamp voltage or a maximum lamp current applied to the plurality of lamps, according to an equation below:
Difference effect size(n)=(maximum lamp voltage or maximum lamp current(n)−maximum lamp voltage or maximum lamp current(n−1))/standard deviation of the maximum lamp voltage or maximum lamp current in a predetermined lot range,
and the controller further calculates a second-order difference effect size (n) by using an equation below:
Second-order difference effect size(n)=Difference effect size(n)−Difference effect size(n−1), or(Difference(n)of maximum lamp voltage or maximum lamp current−Difference(n−1)of maximum lamp voltage or maximum lamp current)/standard deviation of difference(n)of maximum lamp voltage or maximum lamp current in predetermined lot range,
and determines that an abnormality has occurred when the difference effect size (n) exceeds a first threshold and the second-order difference effect size falls within a range over a second threshold and below a third threshold.

5. The heat treatment apparatus according to claim 4, further comprising: a warning unit that issues a warning of the abnormality in the heat treatment apparatus by a display or a voice,
wherein when the controller determines that an abnormality has occurred, the warning unit issues the warning.

6. The heat treatment apparatus according to claim 4, wherein the first threshold is 1.2 or more and 3.0 or less, the second threshold is −1.5 or more and −0.7 or less, and the third threshold is 0.7 or more and 1.5 or less.

7. A manufacturing method for manufacturing a semiconductor substrate, using the heat treatment apparatus according to claim 1 that continuously performs heat treatment on a plurality of semiconductor substrates on a lot basis, the semiconductor substrate manufacturing method comprising:
a step of controlling, by the controller, a lamp voltage or a lamp current applied to a plurality of lamps and heating a semiconductor substrate using the plurality of lamps; and
a step of detecting, by the controller, the temperature of the semiconductor substrate using the temperature detector and controlling the lamp voltage or the lamp current applied to the plurality of lamps based on the temperature of the semiconductor substrate,
wherein, when n is a positive integer of 2 or more indicating the order of a lot, the controller calculates a difference effect size (n), based on a maximum lamp voltage or a maximum lamp current applied to the plurality of lamps, according to an equation below:
Difference effect size(n)=(maximum lamp voltage or maximum lamp current(n)−maximum lamp voltage or maximum lamp current(n−1))/standard deviation of the maximum lamp voltage or maximum lamp current in a predetermined lot range,
and determines that an abnormality has occurred when the difference effect size (n) exceeds a first threshold.

8. The semiconductor substrate manufacturing method according to claim 7, wherein
a warning unit that issues a warning of an abnormality in the heat treatment apparatus by a display or a voice warns of the abnormality when the controller determines that an abnormality has occurred.

9. The semiconductor substrate manufacturing method according to claim 7, wherein the first threshold is 1.2 or more and 3.0 or less.
